(19) United States
(12) Patent Application Publication
(10) Pub. No.: US 2025/0359375 A1
(43) Pub. Date: Nov. 20, 2025

(54) IMAGING DEVICE

(71) Applicant: SONY SEMICONDUCTOR SOLUTIONS CORPORATION, Atsugi-shi (JP)

(72) Inventors: RYOSUKE MATSUMOTO, KANAGAWA (JP); KEIGO NAKAMURA, KANAGAWA (JP)

(21) Appl. No.: 18/874,687

(22) PCT Filed: Jun. 21, 2022
(86) PCT No.: PCT/JP2022/024729

§ 371 Date: Dec. 13, 2024

(51) Int. Cl. H10F 39/00; H10F 39/18

(52) U.S. Cl. CPC H10F 39/807; H10F 39/014; H10F 39/184; H10F 39/811

(57) ABSTRACT

To improve optical characteristics and suppress dark current.

An imaging device includes: a plurality of pixels; and a pixel boundary region disposed between two of the pixels adjacent to each other, in which each of the pixels includes: a photoelectric conversion layer containing a compound semiconductor material; a first electrode that is disposed on a light incident surface side of the photoelectric conversion layer and contains a compound semiconductor material; and a second electrode that is disposed on an opposite surface side with respect to the light incident surface side of the photoelectric conversion layer and transfers a charge photoelectrically converted in the photoelectric conversion layer, the pixel boundary region includes: a high-concentration impurity region extending from the light incident surface side to the opposite surface side; a third electrode electrically insulated from the high-concentration impurity region and disposed along the high-concentration impurity region; and a fourth electrode electrically conducted to the first electrode.

### TECHNICAL FIELD

The present disclosure relates to an imaging device.

### BACKGROUND ART

In an infrared sensor having sensitivity in an infrared region, a photoelectric conversion layer containing a compound semiconductor material such as indium gallium arsenide (InGaAs) or indium phosphide (InP), for example, is used.

In an infrared sensor of this type, an impurity concentration gradient is not applied to the photoelectric conversion layer, so that it is necessary to dispose an electrode not only on the pixel circuit side of the photoelectric conversion layer but also on the light incident surface side. In addition, it is necessary to suppress dark current caused by crystal defects or the like in the photoelectric conversion layer. For this reason, a technique has been proposed in which a transparent electrode is disposed on the light incident surface side of a photoelectric conversion layer and an impurity diffusion region is provided in a boundary region between two adjacent pixels to suppress generation of dark current (see, for example, Patent Document 1).

### CITATION LIST

### Patent Document

Patent Document 1: WO 2018/212175 A1

### SUMMARY OF THE INVENTION

### Problems to be Solved by the Invention

However, when a transparent electrode is disposed on the light incident surface side of the photoelectric conversion layer, optical characteristics of infrared rays may be deteriorated to some extent. In addition, in a case where an impurity diffusion region is disposed in the boundary region between two adjacent pixels, the effect of suppressing dark current cannot be sufficiently obtained unless the voltage applied to the impurity diffusion region is optimized.

Therefore, the present disclosure provides an imaging device having excellent optical characteristics and capable of suppressing dark current.

### Solutions to Problems

In order to solve the above-described problem, according to the present disclosure, there is provided an imaging device including:
a plurality of pixels; and
a pixel boundary region disposed between two of the pixels adjacent to each other, in which
each of the pixels includes:
a photoelectric conversion layer containing a compound semiconductor material;
a first electrode that is disposed on a light incident surface side of the photoelectric conversion layer and contains a compound semiconductor material; and
a second electrode that is disposed on an opposite surface side with respect to the light incident surface side of the photoelectric conversion layer and transfers a charge photoelectrically converted in the photoelectric conversion layer, and
the pixel boundary region includes:
a high-concentration impurity region extending from the light incident surface side to the opposite surface side;
a third electrode electrically insulated from the high- concentration impurity region and disposed along the high- concentration impurity region; and
a fourth electrode electrically conducted to the first electrode.

The high-concentration impurity region may have an impurity content per unit volume higher than the photoelectric conversion layer.

The third electrode may be set to a voltage that induces a specific charge in the high-concentration impurity region.

The specific charge may be a charge having a polarity different from a polarity of a charge photoelectrically converted in the photoelectric conversion layer and transferred to the second electrode.

The first electrode may be a semiconductor layer containing a compound semiconductor material different from the compound semiconductor material of the photoelectric conversion layer.

The fourth electrode may be disposed from the opposite surface side with respect to the light incident surface side of the photoelectric conversion layer to a height reacting the first electrode.

The third electrode may be disposed between the fourth electrode and the high-concentration impurity region.

The third electrode may be disposed from the opposite surface side with respect to the light incident surface side of the photoelectric conversion layer to a height not reaching the first electrode.

The high-concentration impurity region may be disposed to surround the pixel, and
the third electrode may be disposed to surround the high-concentration impurity region for each of the pixels.

The plurality of pixels may be arranged in a first direction and a second direction,
two of the third electrodes included in two of the pixels disposed adjacent to each other in the first direction may be connected at the pixel boundary region between the two of the pixels disposed adjacent to each other in the first direction, and
two of the third electrodes included in two of the pixels disposed adjacent to each other in the second direction may be connected at the pixel boundary region between the two of the pixels disposed adjacent to each other in the second direction.

The fourth electrode may be disposed in the pixel boundary region between two of the pixels disposed adjacent to each other in a diagonal direction.

The imaging device may further include a wiring layer disposed on the opposite surface side with respect to the light incident surface side of the photoelectric conversion layer, and the wiring layer may include, for each of the pixels:
a first wiring region electrically conducted to the second electrode; and
a second wiring region electrically conducted to the fourth electrode.

The wiring layer may include, for each of the pixels, a third wiring region electrically conducted to the third electrode.

An end portion of the high-concentration impurity region on the light incident surface side may be connected to the first electrode, and
an end portion of the high-concentration impurity region on the opposite surface side with respect to the light incident surface side may be connected to the fourth electrode.

The high-concentration impurity region may be disposed to surround the pixel, and
the fourth electrode may be disposed to surround the high-concentration impurity region for each of the pixels.

The third electrode may be disposed in a lattice pattern in a plurality of the pixel boundary regions between the plurality of pixels.

The imaging device may further include a wiring layer disposed on the opposite surface side with respect to the light incident surface side of the photoelectric conversion layer, and
the wiring layer may include, for each of the pixels, a first wiring region electrically conducted to the second electrode.

The wiring layer may include, for each of the pixels, a second wiring region electrically conducted to the fourth electrode.

A plurality of the third electrodes provided in a plurality of the pixel boundary regions between the plurality of pixels may be electrically conducted to each other, and
a plurality of the fourth electrodes provided in a plurality of the pixel boundary regions may be electrically conducted to each other.

### BRIEF DESCRIPTION OF DRAWINGS

FIG. 1 is a block diagram illustrating an outline of an imaging device according to the present disclosure.

FIG. 2 is a schematic diagram illustrating a laminated structure of the imaging device according to the present disclosure.

FIG. 3 is a plan view of a pixel region in a first embodiment of the present disclosure.

FIG. 4A is a cross-sectional view taken along line A-A of the pixel region in FIG. 3.

FIG. 4B is a cross-sectional view taken along line B-B of the pixel region in FIG. 3.

FIG. 5 is a schematic diagram illustrating a state in which charges move in the pixel according to the first embodiment of the present disclosure.

FIG. 6A is a cross-sectional view of an imaging device according to a first comparative example.

FIG. 6B is a cross-sectional view of an imaging device according to a second comparative example.

FIG. 7A is a view illustrating a step of forming a laminate.

FIG. 7B is a view illustrating a step of forming a trench in the laminate.

FIG. 7C is a view illustrating a step of forming an impurity diffusion region in the laminate.

FIG. 7D is a view illustrating a step of forming a pinning electrode in the laminate in the cross-sectional view taken along line A-A of the pixel region in FIG. 3.

FIG. 7E is a view illustrating a step of forming the pinning electrode in the laminate in the cross-sectional view taken along line B-B of the pixel region in FIG. 3.

FIG. 7F is a view illustrating a step of digging a groove region of the laminate in the cross-sectional view taken along line A-A of the pixel region in FIG. 3.

FIG. 7G is a view illustrating a step of covering the pinning electrode and a transfer electrode of the laminate with an insulating material, in the cross-sectional view taken along line A-A of the pixel region in FIG. 3.

FIG. 7H is a view illustrating a step of covering the pinning electrode and the transfer electrode of the laminate with the insulating material, in the cross-sectional view taken along line B-B of the pixel region in FIG. 3.

FIG. 7I is a view illustrating a step of forming a trench for a through electrode of the laminate in the cross-sectional view taken along line A-A of the pixel region in FIG. 3.

FIG. 7J is a view illustrating a step of forming the through electrode of the laminate in the cross-sectional view taken along line A-A of the pixel region in FIG. 3.

FIG. 8A is a cross-sectional view illustrating an example of wiring connection between the transfer electrode of the pixel, the through electrode, and the pinning electrode, and the pixel circuit, according to the first embodiment of the present disclosure.

FIG. 8B is a cross-sectional view illustrating an example of wiring connection between the transfer electrode of the pixel and the through electrode, and the pixel circuit, according to the first embodiment of the present disclosure.

FIG. 9 is view illustrating a cross-sectional structure of an imaging device in a first modification of the first embodiment of the present disclosure.

FIG. 10 is a plan view of a pixel region in a second modification of the first embodiment of the present disclosure.

FIG. 11 is a cross-sectional view taken along line B-B of the pixel region in FIG. 10.

FIG. 12 is a plan view of a pixel region in a third modification of the first embodiment of the present disclosure.

FIG. 13 is a plan view of a pixel region in a fourth modification of the first embodiment of the present disclosure.

FIG. 14 is a cross-sectional structure of an imaging device in a fifth modification of the first embodiment of the present disclosure.

FIG. 15 is a plan view of a pixel region in a second embodiment of the present disclosure.

FIG. 16 is a cross-sectional view taken along line C-C of the pixel region in FIG. 15.

FIG. 17A is a view illustrating a step of forming a pinning electrode and a transfer electrode in a laminate.

FIG. 17B is a view illustrating a step of forming an insulating layer in the laminate.

FIG. 17C is a view illustrating a step of forming a groove portion in the insulating layer of the laminate.

FIG. 17D is a view illustrating a step of forming a trench in the insulating layer of the laminate.

FIG. 17E is a view illustrating a step of forming an electrode in the insulating layer of the laminate.

FIG. 18A is a cross-sectional view illustrating an example of wiring connection between the transfer electrode and the electrode of the pixel, and the pixel circuit, according to the second embodiment of the present disclosure.

FIG. 18B is a cross-sectional view illustrating an example of wiring connection between the electrode of the pixel and the pixel circuit, according to the second embodiment of the present disclosure.

FIG. 19 is a cross-sectional view of an imaging device in a first modification of the second embodiment of the present disclosure.

FIG. 20 is a cross-sectional view of an imaging device in a second modification of the second embodiment of the present disclosure.

FIG. 21 is a block diagram illustrating an example of a schematic configuration of a vehicle control system.

FIG. 22 is an explanatory view illustrating an example of installation positions of an outside-vehicle information detection unit and an imaging unit.

### MODE FOR CARRYING OUT THE INVENTION

Hereinafter, embodiments of an imaging device will be described with reference to the drawings. Although main components of the imaging device will be mainly described below, the imaging device may have components and functions that are not illustrated or described. The following description does not exclude components and functions that are not illustrated or described.

### Outline of Imaging Device

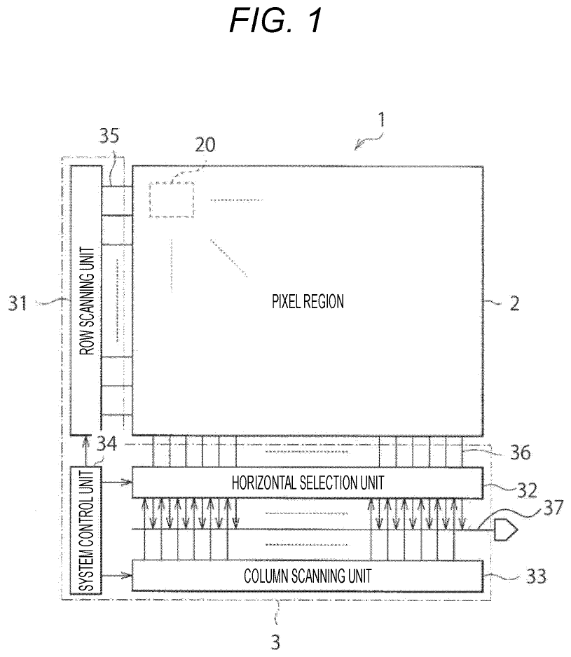

FIG. 1 is a block diagram illustrating an outline of an imaging device 1 according to the present disclosure. The imaging device 1 according to the present disclosure images light in an infrared band, for example. The imaging device 1 according to the present disclosure includes a pixel region 2 and a circuit unit 3. The circuit unit 3 includes a row scanning unit 31, a horizontal selection unit 32, a column scanning unit 33, and a system control unit 34.

The pixel region 2 has a configuration in which a plurality of pixels 20 is two-dimensionally arranged in a matrix. Here, the column direction is a direction in which a plurality of pixel drive lines 35 is disposed, and is a direction in which each signal line 36 extends. The row direction is a direction in which the plurality of signal lines 36 is disposed, and is a direction in which each pixel drive line 35 extends. In the present description, the pixels 20 in one row arranged in the row direction are referred to as a pixel row, and the pixels 20 of one column arranged in the column direction are referred to as a pixel column. In the pixel region 2, the pixel drive line 35 is disposed for each pixel row. One end of the pixel drive line 35 is connected to an output end corresponding to each row of the row scanning unit 31. Furthermore, a signal line 36 is disposed for each pixel column. Each signal line 36 transmits pixel signals output from each pixel 20 in the corresponding pixel column.

Although not illustrated, the row scanning unit 31 and the column scanning unit 33 include a shift register, an address decoder, and the like. Furthermore, the horizontal selection unit 32 includes an amplifier, a horizontal selection switch, and the like. As described above, the plurality of pixel drive lines 35 is connected to the row scanning unit 31. The row scanning unit 31 sequentially drives the plurality of pixel drive lines 35 to sequentially select corresponding pixel rows in the pixel region 2. Each pixel 20 in the selected pixel row supplies a pixel signal to the horizontal selection unit 32 via the corresponding signal line 36. The column scanning unit 33 controls selection of a signal line by the horizontal selection unit 32. Under the control by the column scanning unit 33, the horizontal selection unit 32 sequentially selects pixel signals on the plurality of signal lines and supplies the selected pixel signal to a signal processing unit (not illustrated) or the like via a signal line 37 extending in the horizontal direction.

The system control unit 34 receives a clock provided from the outside, and synchronously controls the row scanning unit 31, the horizontal selection unit 32, the column scanning unit 33, and the like. Furthermore, the system control unit 34 receives data for instruction of an operation mode and outputs data such as internal information of the imaging device 1.

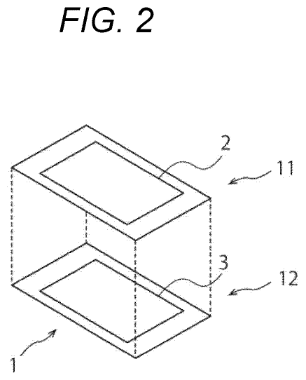

FIG. 2 is a schematic diagram illustrating the laminated structure of the imaging device 1 according to the present disclosure. The imaging device 1 according to the present disclosure can be configured with, for example, a laminated structure of semiconductor chips. The imaging device 1 in FIG. 2 is configured by laminating a pixel chip 11 in which a pixel region 2 is disposed and a circuit chip 12 in which a pixel circuit, a circuit unit 3, and the like are disposed. These chips are connected by Cu-Cu bonding or the like and transmit various signals. Note that the pixel chip 11 and the circuit chip 12 may be connected by a via, a bump, or the like in addition to Cu-Cu bonding. However, the imaging device 1 is not limited to have the laminated structure as illustrated in FIG. 2. For example, the imaging device 1 may have a flat chip structure in which the pixel region 2 and the circuit unit 3 are disposed on the same chip.

### First Embodiment of Present Disclosure

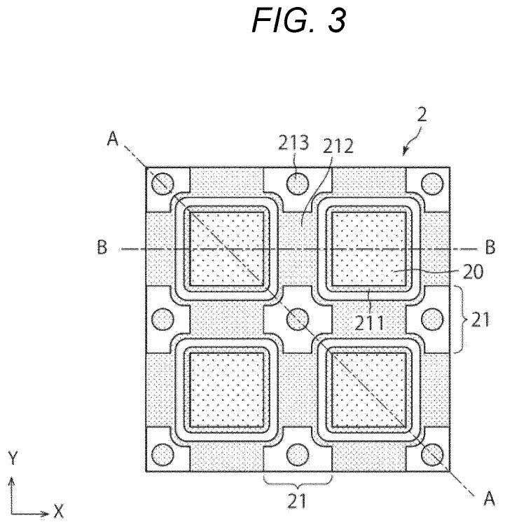

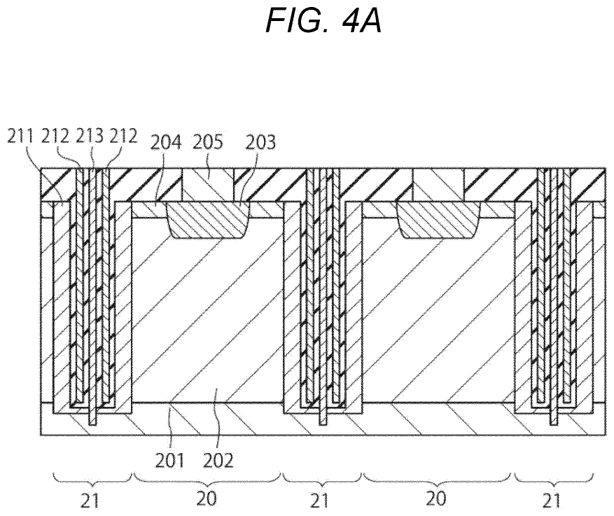

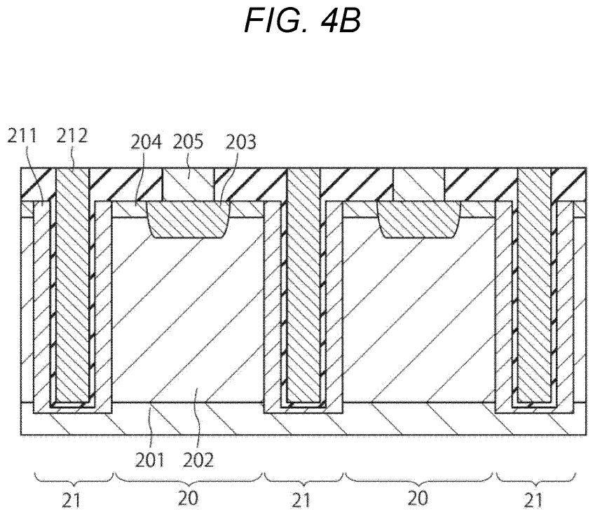

FIGS. 3, 4A, and 4B are a plan view and cross-sectional views illustrating a structure of the pixel region 2 according to a first embodiment of the present disclosure. FIG. 3 is a plan view of the pixel region 2. As illustrated in FIG. 3, the pixel region 2 includes a plurality of pixels 20 arranged two-dimensionally. A pixel boundary region 21 is provided between two of the pixels 20 disposed adjacent to each other in a first direction X and between two of the pixels 20 disposed adjacent to each other in a second direction Y.

As illustrated in FIG. 3, in the pixel boundary region 21, a high-concentration impurity region 211, a pinning electrode 212 (third electrode), and a through electrode 213 (fourth electrode) are provided. The high-concentration impurity region 211 is provided for each pixel 20 and is disposed to surround the pixel 20. Details of the high-concentration impurity region 211 will be described later. The pinning electrode 212 is provided for each pixel 20, and is disposed to surround the pixel 20 and the high-concentration impurity region 211. The pinning electrode 212 is connected to the pinning electrodes 212 adjacent thereto in the first direction X and the second direction Y. The through electrode 213 is disposed between each two of the pixels 20 adjacent to each other in the diagonal direction.

FIG. 4A is a cross-sectional view taken along line A-A in FIG. 3, and FIG. 4B is a cross-sectional view taken along line B-B in FIG. 3. FIG. 4A illustrates a cross-sectional structure of two of the pixels 20 adjacent in the diagonal direction, and FIG. 4B illustrates a cross-sectional structure of two of the pixels 20 adjacent in the first direction X. In FIGS. 4A and 4B, the light incident surface is illustrated on the lower side.

As illustrated in FIG. 4A, the pixel 20 is provided with a contact layer 201 (first electrode), a photoelectric conversion layer 202, an impurity diffusion region 203, a contact layer 204, and a transfer electrode 205 (second electrode) in order from the light incident surface side in the lamination direction. In the pixel boundary region 21, the high-concentration impurity region 211, the pinning electrode 212 (third electrode), and the through electrode 213 (fourth electrode) are separately provided. The contact layer 201 and the contact layer 204 are disposed opposite to each other.

The contact layers 201 and 204 are semiconductor layers containing a compound semiconductor material (for example, InP). The impurity diffusion region 203 is a region in which impurities are implanted into a part of the contact layer 204 and diffused. A charge generated by photoelectric conversion in the photoelectric conversion layer 202 is transferred to the transfer electrode 205 by a bias voltage applied between the transfer electrode 205 connected to the contact layer 204 and the impurity diffusion region 203, and the contact layer 201.

The photoelectric conversion layer 202 is, for example, a semiconductor layer containing a compound semiconductor material (for example, InGaAs) different from those of the contact layers 201 and 204. The photoelectric conversion layer 202 is disposed between the contact layers 201 and 204. The photoelectric conversion layer 202 is a light absorbing layer. The photoelectric conversion layer 202 absorbs light transmitted through the contact layer 201 and generates signal charges.

The transfer electrode 205 is an electrode to which a voltage for reading charges accumulated in the photoelectric conversion layer 202 as signal charges is supplied. The transfer electrode 205 is provided for each pixel 20, and is electrically connected to a pixel circuit (not illustrated). Between the transfer electrode 205 and the photoelectric conversion layer 202, two or more semiconductor layers having a band cap energy larger than the band cap energy of the photoelectric conversion layer 202 and having a conductivity type different therefrom may be disposed and a depletion region may be formed in the vicinity of these semiconductor layers to suppress dark current.

The high-concentration impurity region 211 disposed to surround the pixel 20 in the pixel boundary region 21 is a region having a higher impurity content per unit volume than the photoelectric conversion layer 202. The high-concentration impurity region 211 is provided mainly for suppressing dark current. The high-concentration impurity region 211 may be, for example, a region in which impurities are implanted and diffused, or may be a region in which a compound semiconductor layer containing impurities is epitaxially grown from a sidewall of a trench formed in the pixel boundary region 21 toward the inner part of the pixel 20.

The pinning electrode 212 is used to induce a specific charge (for example, a hole) in the high-concentration impurity region 211. The pinning electrode 212 extends from an opposite surface side with respect to the light incident surface side of the pixel 20 to a height at which the pinning electrode 212 is not in contact with the contact layer 201. The pinning electrode 212 is disposed between the high-concentration impurity region 211 and the through electrode 213. Although an insulating material is disposed between the pinning electrode 212 and the high-concentration impurity region 211, the charge induced in the high-concentration impurity region 211 can be controlled by controlling the voltage applied to the pinning electrode 212. More specifically, the pinning electrode 212 can induce a charge having a polarity opposite to that of the charge transferred to the transfer electrode 205 in the high-concentration impurity region 211.

The through electrode 213 is an electrode used to apply a bias voltage to the contact layer 201. The through electrode 213 is disposed from an opposite surface side with respect to the light incident surface side of the pixel 20 to a height at which the through electrode 213 reaches the contact layer 201. Furthermore, an insulating material is disposed between the through electrode 213 and the high-concentration impurity region 211.

As illustrated in FIG. 4B, the two pinning electrodes 212 arranged in the layer direction in the pixel boundary regions 21 of the two pixels 20 adjacent in the first direction X in FIG. 3 are electrically connected to each other. The same applies to the two pinning electrodes 212 disposed in the pixel boundary region 21 of the two pixels 20 adjacent in the second direction Y in FIG. 3.

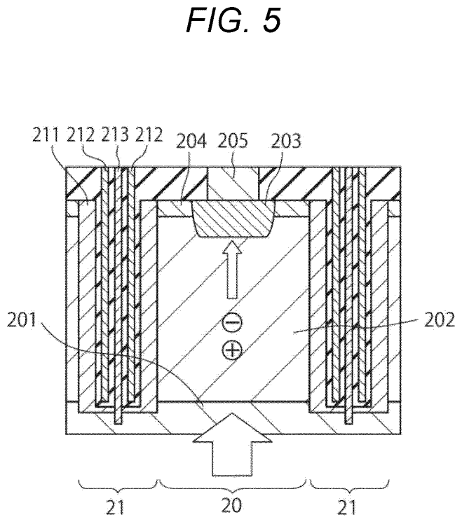

FIG. 5 is a schematic diagram illustrating a state in which charges move in the pixel 20 according to the first embodiment of the present disclosure. The configuration of the pixel 20 and the pixel boundary region 21 illustrated in FIG. 5 is the same as that in FIG. 4A. A reverse bias voltage is applied to the pixel 20 by the contact layers 201 and 204. In addition, the high-concentration impurity region 211 cancels a charge caused by a crystal defect or the like by a charge induced in the high-concentration impurity region 211, by a voltage applied to the pinning electrode 212, thereby preventing dark current from being read at the transfer electrode 205. For example, in a case where the transfer electrode 205 transfers electrons, the voltage applied to the pinning electrode 212 is controlled to induce holes in the high-concentration impurity region 211.

As described above, when a predetermined voltage for reading a specific charge (for example, an electron) is applied to the transfer electrode 205, a potential gradient is generated, and electrons generated by photoelectric conversion are attracted to the transfer electrode 205. The electrons transferred to the transfer electrode 205 are subjected to charge-voltage conversion in the pixel circuit to generate a pixel signal.

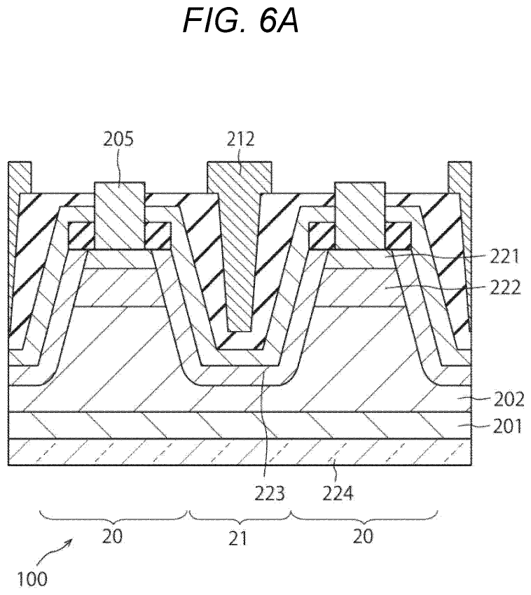

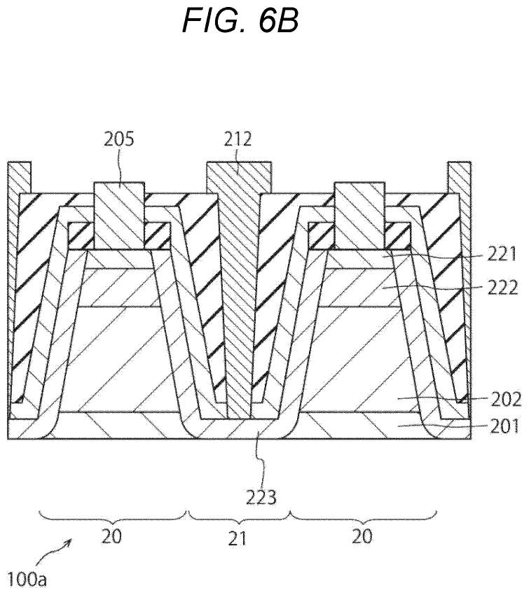

FIG. 6A is a cross-sectional view of an imaging device 100 according to a first comparative example, and FIG. 6B is a cross-sectional view of an imaging device 100a according to a second comparative example. The imaging devices 100 and 100a in FIGS. 6A and 6B include pixels 20 in each of which a first semiconductor layer 221, a second semiconductor layer 222, and a photoelectric conversion layer 202 are laminated. Furthermore, in the pixel boundary region 21 between two of the pixels 20 adjacent to each other, a diffusion layer 223, a coating film, and a protective film are laminated in the pixel boundary region 21 between two of the pixels 20 that are adjacent to each other. On the light incident surface side of the photoelectric conversion layer 202, the contact layer 201 is disposed.

In the imaging device 100 in FIG. 6A, a transparent electrode 224 laminated on the contact layer 201 is provided instead of the through electrode 213 in FIG. 4A. In the example of FIG. 6A, the bias voltage is applied to the contact layer 201 by the transparent electrode 224. In the first comparative example, the pinning electrode 212 is provided in the pixel boundary region 21, and the voltage applied to the pinning electrode 212 is controlled to induce charges of a desired polarity in the diffusion layer 223, so that dark current can be suppressed. However, since the transparent electrode 224 is disposed on the light incident surface side of the photoelectric conversion layer 202, optical characteristics of the imaging device 100 may be deteriorated.

In the imaging device 100a in FIG. 6B, the pinning electrode 212 is disposed to a height at which the pinning electrode 212 reaches the contact layer 201. As a result, the potential of the contact layer 201 can be set by the voltage applied to the pinning electrode 212, and the transparent electrode 224 becomes unnecessary. Therefore, there is no possibility that the optical characteristics of infrared rays are deteriorated due to the transparent electrode 224. However, since the pinning electrode 212 is electrically connected to the contact layer 201 and the contact layer 201 is in contact with the diffusion layer 223, there is a possibility that charges of a desired polarity cannot be induced in the diffusion layer 223. Therefore, the effect of suppressing dark current may not be sufficiently obtained.

As described above, as compared with the first comparative example and the second comparative example, the imaging device 1 according to the first embodiment of the present disclosure illustrated in FIG. 4A applies the bias voltage to the contact layer 201 not by the transparent electrode 224 but by the through electrode 213 in the pixel boundary region 21. Furthermore, the high-concentration impurity region 211 is set, by the pinning electrode 212, to an optimum voltage for suppressing dark current. As a result, the imaging device 1 according to the first embodiment of the present disclosure can suppress dark current and improve optical characteristics.

### Steps of Manufacturing Imaging Device according to First Embodiment of Present Disclosure

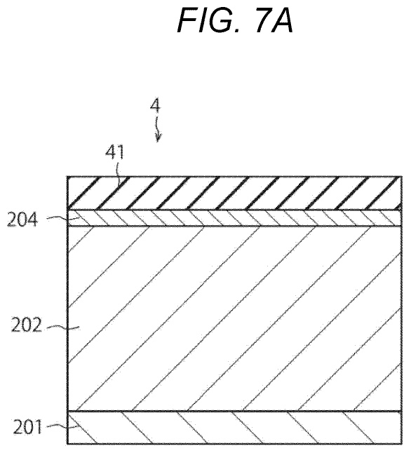

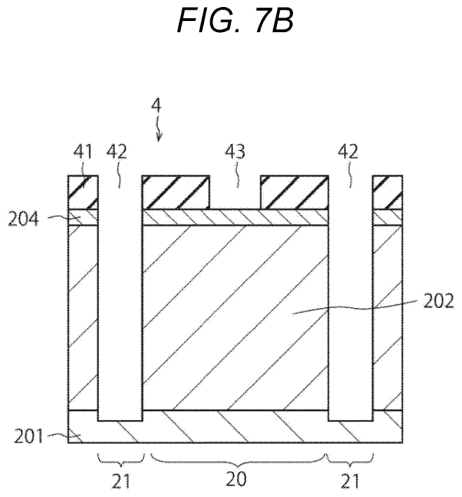

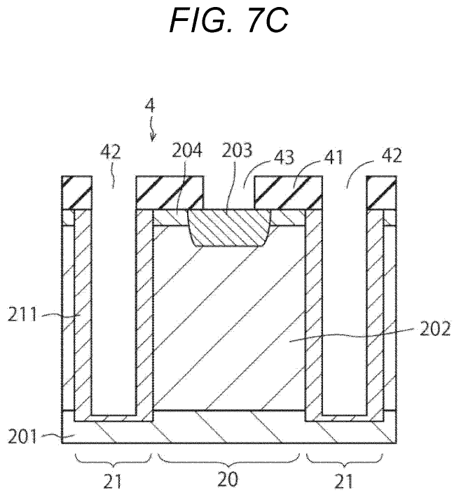

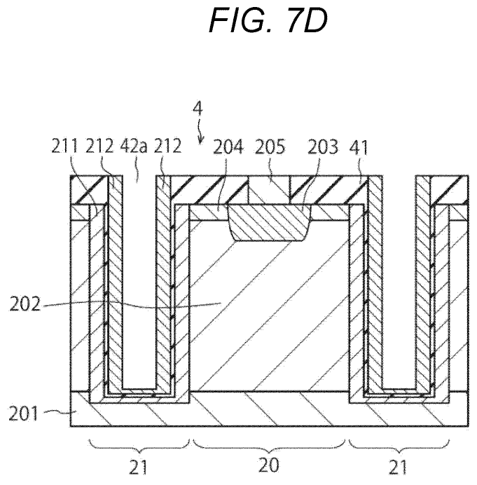

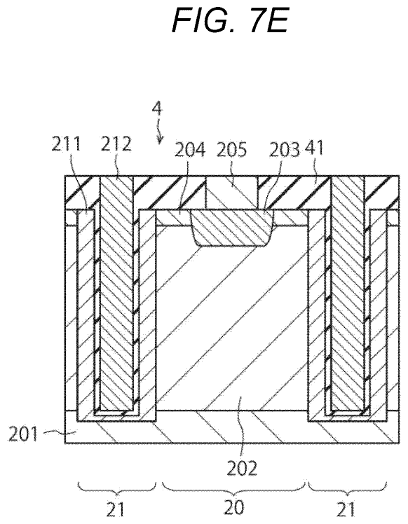

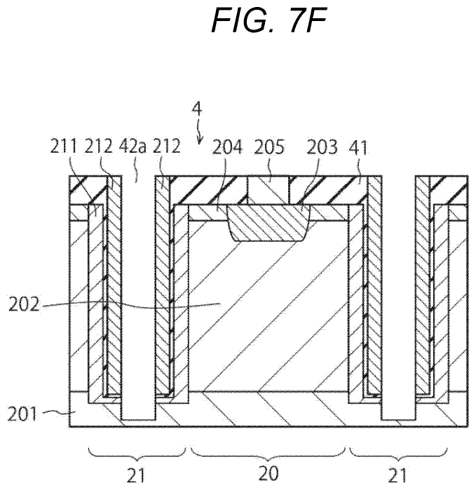

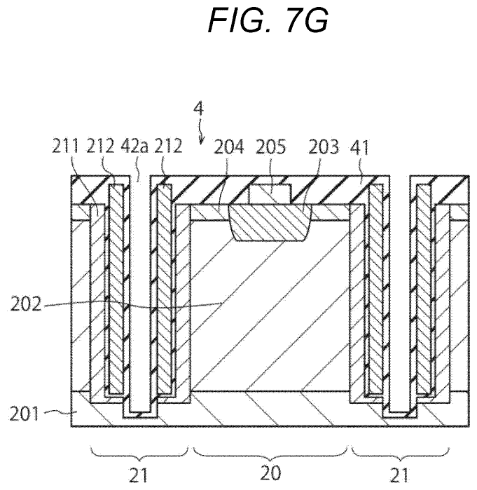

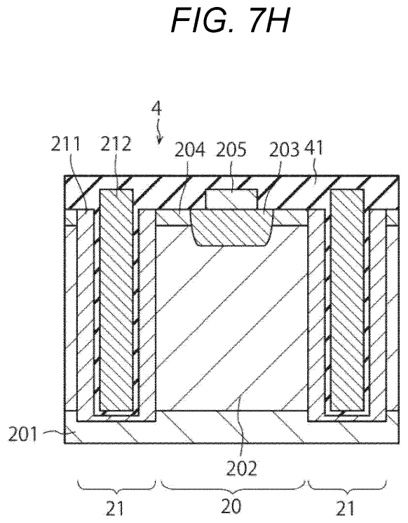

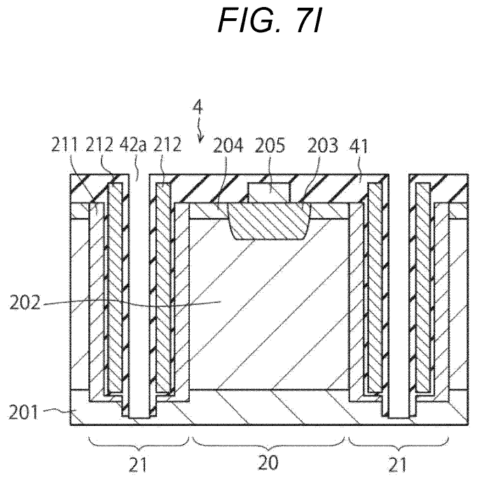

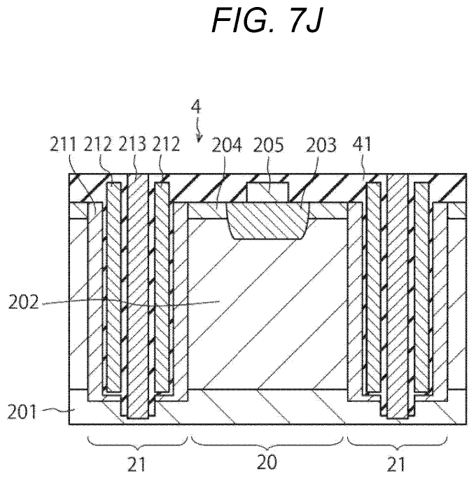

Next, an outline of steps of manufacturing the imaging device 1 according to the first embodiment of the present disclosure will be described. FIGS. 7A to 7J are views of the steps of manufacturing the imaging device 1 according to the first embodiment of the present disclosure. First, as illustrated in FIG. 7A, a laminate 4 in which the contact layer 201, the photoelectric conversion layer 202, the contact layer 204, and an insulating layer 41 are sequentially laminated is formed. Next, as illustrated in FIG. 7B, a part of the laminate 4 is removed by etching or the like to form a trench 42. The trench 42 is formed such that the bottom portion reaches the contact layer 201, and is provided in the pixel boundary region 21. In addition, a trench 43 having a height reaching the contact layer 204 is formed at a position where the transfer electrode 205 is formed. Next, as illustrated in FIG. 7C, a high-concentration impurity diffusion region (high-concentration impurity region 211) is formed along the sidewall of each of the trench 42, and impurities are implanted into the bottom of the trench 43 to form the impurity diffusion region 203. The polarity of the impurity contained in the high-concentration impurity region 211 and the polarity of the impurity contained in the impurity diffusion region 203 are different from each other. For example, the high-concentration impurity region 211 contains a p-type impurity (for example, zinc, magnesium, or the like), and the impurity diffusion region 203 contains an n-type impurity (for example, sulfur, germanium, or the like). The impurity amount per unit volume contained in the high- concentration impurity region 211 is made larger than the impurity amount per unit volume contained in the photoelectric conversion layer 202. The high-concentration impurity region 211 may be a diffusion region in which impurities are implanted into the sidewalls from the trench 42 and diffused, or a semiconductor layer containing impurities formed by epitaxial growth from the sidewalls of the trench 42. The impurity diffusion region 203 is a diffusion region in which impurities are implanted into the bottom of the trench 43 and diffused.

Next, as illustrated in FIGS. 7D and 7E, the inner walls of the trenches 42 and 43 are covered with an insulating material, and then further covered with a metal material. This metal material is for the pinning electrodes 212 and the transfer electrode 205, and is a highly conductive material such as copper or aluminum. FIG. 7D is a cross-sectional view taken along line A-A in FIG. 3, and FIG. 7E is a cross-sectional view taken along line B-B in FIG. 3. In the trench 43 in FIGS. 7D and 7E, the transfer electrode 205 is formed. Since the width of the trench 42 in the A-A line direction in FIG. 3 is larger than the width of the trench 42 in the B-B line direction in FIG. 3, in the trench 42 in the A-A line direction in FIG. 3, a groove region 42a not filled with the metal material is formed as illustrated in FIG. 7D, whereas the inner wall portion of the trench 42 in the B-B line direction in FIG. 3 is filled with the metal material as illustrated in FIG. 7E. Therefore, in the A-A line direction in FIG. 3, after the step of FIG. 7D, the bottom of the groove region 42a is dug down by etching or the like to reach the contact layer 201 as illustrated in FIG. 7F.

Next, as illustrated in FIGS. 7G and 7H, the inner wall of the groove region 42a is covered with an insulating material. FIG. 7G is a cross-sectional view taken along line A-A in FIG. 3, and FIG. 7H is a cross-sectional view taken along line B-B in FIG. 3. After the step of FIG. 7G, the bottom of the groove region 42a is dug down again by etching or the like to reach the contact layer 201 as illustrated in FIG. 71. Next, as illustrated in FIG. 7J, the inner part of the groove region 42a is filled with a metal material to form the through electrode 213.

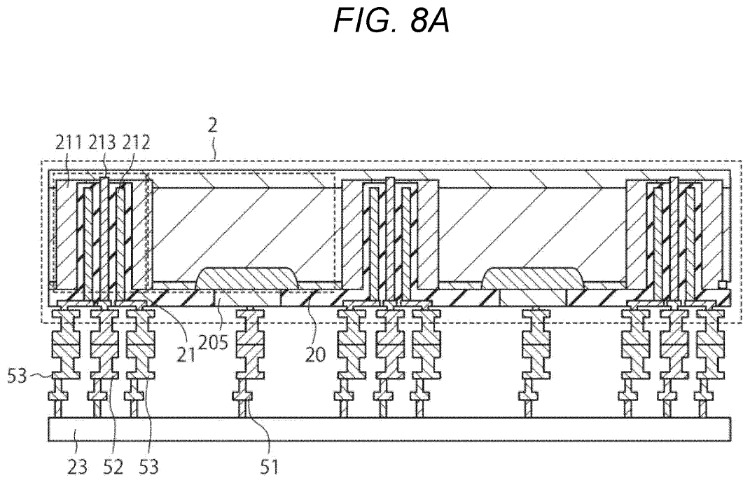

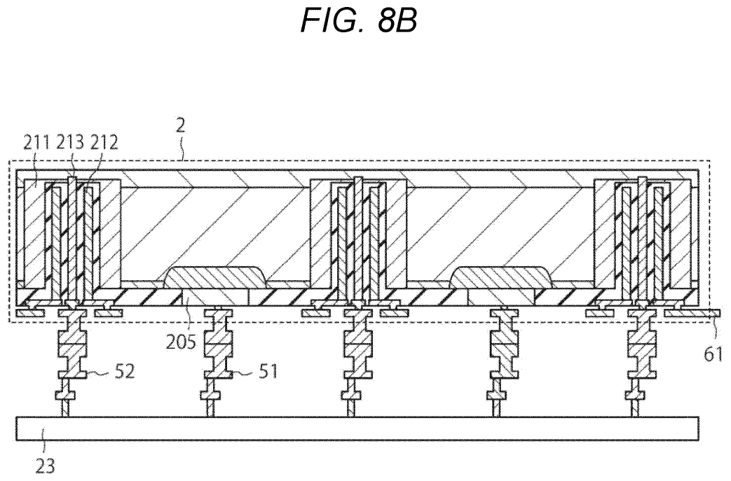

FIGS. 8A and 8B are cross-sectional views illustrating an example of wiring connection between the pixel 20 and the pixel circuit. FIGS. 8A and 8B include the pixel region 2 and the pixel boundary region 21 having a cross-sectional structure similar to that of FIG. 4A. In FIGS. 8A and 8B, the light incident surface is illustrated on the upper side. FIG. 8A includes, for each pixel 20, a first wiring region 51 connected to the transfer electrode 205, a second wiring region 52 connected to the through electrode 213, and a third wiring region 53 connected to the pinning electrode 212. The other end sides of the first to third wiring regions 51, 52, and 53 are all connected to a pixel circuit 23. In the pixel boundary region 21 in FIG. 8A, one second wiring region 52 and two third wiring regions 53 are provided. As described above, since in FIG. 8A, the first to third wiring regions 51, 52, and 53 are separately connected to the transfer electrode 205, the through electrode 213, and the pinning electrode 212 of each pixel 20, the number of wiring regions increases. FIG. 8B is obtained by thinning out the third wiring region 53 from FIG. 8A. Except for the peripheral edge portion of the pixel region 2, the third wiring region 53 is not connected to the pinning electrode 212. To the pinning electrode 212 located at the peripheral edge portion of the pixel region 2, a wiring region 61 extending outward is connected, and the pinning electrode 212 in each pixel boundary region 21 is set to the same voltage level via the wiring region 61.

### First Modification of First Embodiment of Present Disclosure

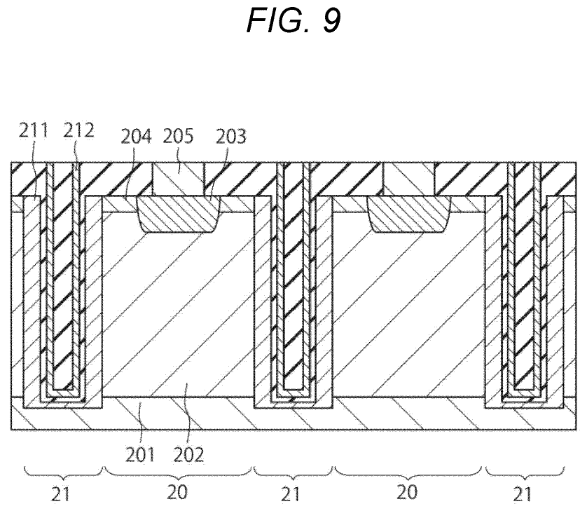

FIG. 9 illustrates a cross-sectional structure of an imaging device 1 in a first modification of the first embodiment of the present disclosure, and is a cross-sectional view taken along line B-B in FIG. 3. In FIG. 9, the shape of a pinning electrode 212 disposed in a pixel boundary region 21 is different from that in FIG. 4B. The pinning electrode 212 in FIG. 9 is a metal layer disposed along the inner wall of the trench formed in the pixel boundary region 21, and the inner part of the metal layer is filled with an insulating material. The pinning electrodes 212 of the adjacent two of pixels 20 are electrically connected to each other via the metal layer at the bottom of the trench. FIG. 9 illustrates a cross-sectional structure of two of the pixels 20 adjacent in the first direction X illustrated in FIG. 3, but the cross-sectional structure of two of the pixels 20 adjacent in the second direction Y is similar.

### Second Modification of First Embodiment of Present Disclosure

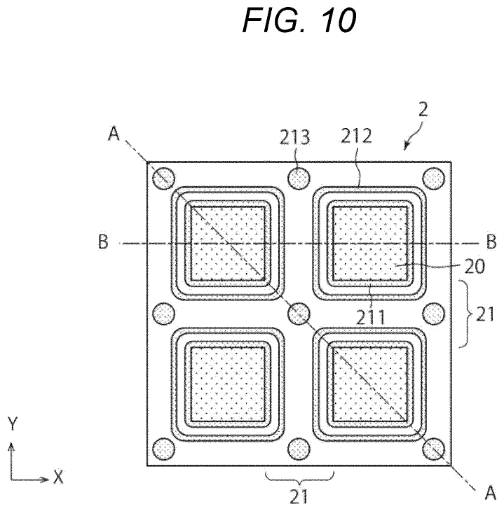

FIG. 10 is a plan view of a pixel region 2 in a second modification of the first embodiment of the present disclosure. In the second modification of the first embodiment of the present disclosure, unlike the configuration of the first embodiment of the present disclosure illustrated in FIG. 3, pinning electrodes 212 of adjacent two of pixels 20 are not connected to each other.

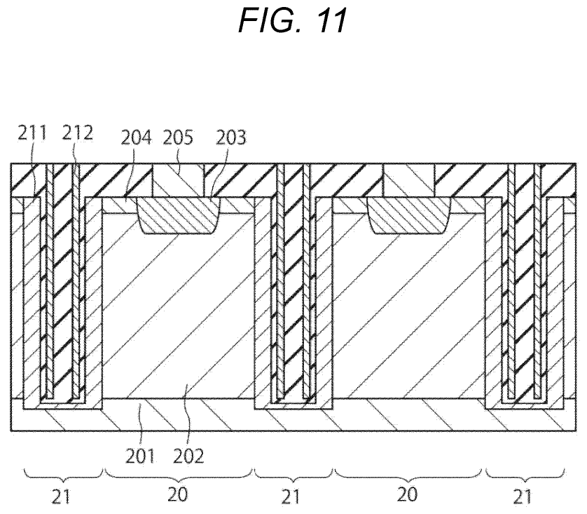

FIG. 11 is a cross-sectional view taken along line B-B in FIG. 10. In FIG. 11, unlike FIG. 4B, the pinning electrodes 212 disposed in pixel boundary regions 21 of the two adjacent pixels 20 are separated from each other by an insulating material. On the other hand, a cross-sectional view taken along line A-A in FIG. 10 is similar to that in FIG. 4A. At this time, the pinning electrode 212 may be individually connected to the pixel circuit of each pixel 20. Furthermore, a wiring layer may be provided between the pixel circuit and the pinning electrodes 212 to connect the pinning electrodes 212 to each other by the wiring layer.

### Third Modification of First Embodiment of Present Disclosure

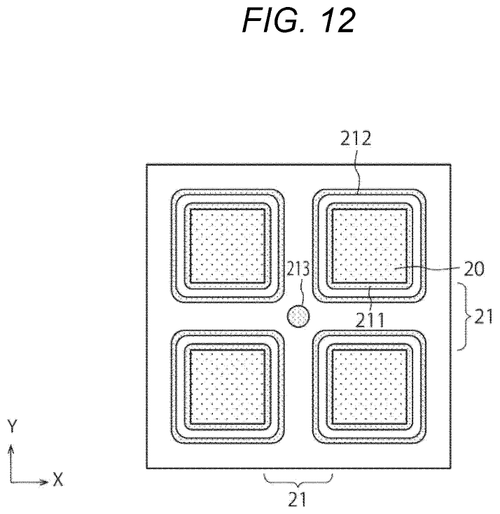

A pinning electrode 212 needs to be provided for each of pixels 20, but a through electrode 213 does not need to be provided for each pixel 20. FIG. 12 is a plan view of a pixel region 2 in a third modification of the first embodiment of the present disclosure. For example, in FIG. 12, unlike the configuration of the first embodiment of the present disclosure illustrated in FIG. 3, the through electrode 213 is disposed at the central portion of four pixels 20 adjacent in the first direction X and the second direction Y, and no other through electrode 213 exists. In this manner, in FIG. 12, the through electrode 213 is provided at a ratio of 1 to the four adjacent pixels 20.

By providing at least one through electrode 213 for four adjacent pixels 20, the voltage level of a contact layer 201 can be set. However, in a case where only one through electrode 213 is provided for four pixels 20 adjacent to each other, conduction of the contact layer 201 becomes incomplete when the through electrode 213 does not reach the contact layer 201 due to manufacturing variations or the like. Therefore, it is desirable to provide two or more through electrodes 213 for four adjacent pixels 20.

### Fourth Modification of First Embodiment of Present Disclosure

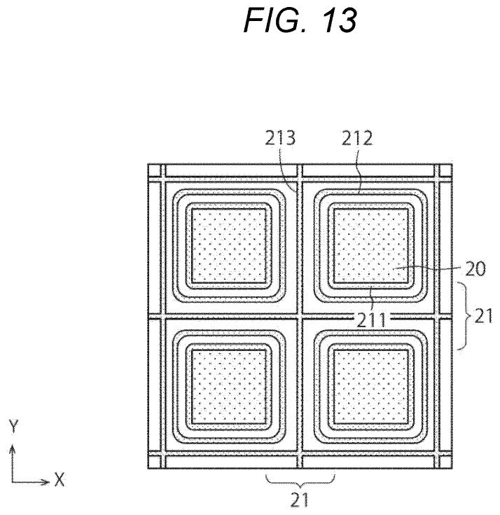

FIG. 13 is a plan view of a pixel region 2 in a fourth modification of the first embodiment of the present disclosure. In the fourth modification of the first embodiment of the present disclosure, a through electrode 213 is disposed in a lattice pattern in a pixel boundary region 21. As a result, the through electrodes 213 is symmetrically connected for all the pixels 20, so that the voltage level of the through electrode 213 can be made common in all the pixels even if there is disconnection or the like in a part.

### Fifth Modification of First Embodiment of Present Disclosure

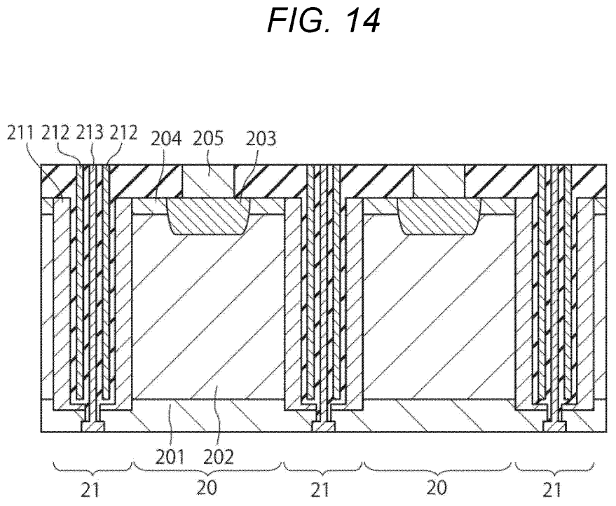

FIG. 14 illustrates a cross-sectional structure of an imaging device 1 in a fifth modification of the first embodiment of the present disclosure, and is a cross-sectional view taken along line A-A in FIG. 3. As illustrated in FIG. 14, in the imaging device 1 in FIG. 14, a through electrode 213 in a pixel boundary region 21 penetrates a contact layer 201. As a result, the light shielding effect is enhanced, so that suppression of color mixing can be expected.

The through electrode 213 illustrated in FIG. 14 may be formed by digging a trench from an opposite surface side with respect to the light incident surface and filling the trench with a metal material, or may be formed by digging a trench from the light incident surface side and filling the trench with metal material. Alternatively, trenches may be dug from both the light incident surface side and the opposite side, and the trenches may be connected to finally form the through electrode 213. The step of digging a trench from the light incident surface side may be performed after a pixel chip 11 and a circuit chip 12 are laminated, or may be performed before the pixel chip 11 and the circuit chip 12 are laminated. The through electrode 213 in FIG. 14 is formed in at least one of a pixel boundary region 21 between two of the pixels 20 adjacent in the first direction X and a pixel boundary region 21 between two of the pixels 20 adjacent in the second direction Y. Furthermore, the length of the through electrode 213 in the depth direction may differ between the pixel boundary region 21 between the two pixels 20 adjacent in the first direction X and the pixel boundary region 21 between the two pixels 20 adjacent in the second direction Y.

As described above, in the first embodiment, in the pixel boundary region 21 between the two pixels 20 adjacent to each other in the first direction X and the second direction Y, the through electrode 213 electrically conducted to the contact layer 201 on the light incident surface side in the pixel 20 is disposed, and the pinning electrode 212 for inducing a specific charge in the high-concentration impurity region 211 disposed in the peripheral edge portion of the pixel 20 is disposed. By providing the through electrode 213 in the pixel boundary region 21, it is not necessary to provide the transparent electrode 224 on the light incident surface side in the pixel 20, and the optical characteristics of the imaging device 1 can be improved. Furthermore, by providing the pinning electrode 212 in the pixel boundary region 21, dark current can be suppressed.

### Second Embodiment of Present Disclosure

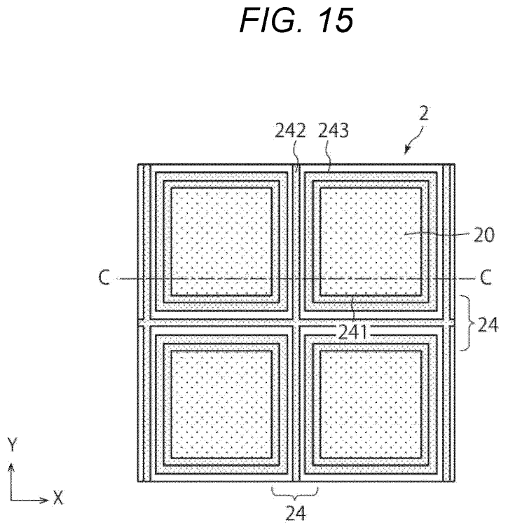

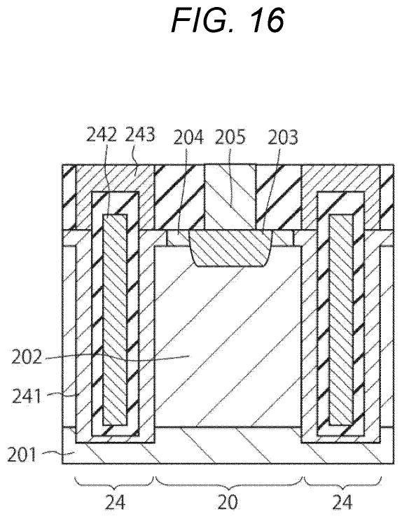

FIGS. 15 and 16 illustrate a pixel structure of an imaging device 1 according to a second embodiment of the present disclosure. FIG. 15 is a plan view of a pixel region 2. The imaging device 1 in FIG. 15 includes a plurality of pixels 20 arranged two-dimensionally. Furthermore, a pixel boundary region 24 is provided between two of pixels 20 disposed adjacent to each other in a first direction X and between two of the pixels 20 disposed adjacent to each other in a second direction Y. In the pixel boundary region 24, a high-concentration impurity region 241, a pinning electrode 242 (third electrode), and an electrode 243 (fourth electrode) are provided. The electrode 243 is disposed to surround the high-concentration impurity region 241. As described later, the electrode 243 is connected to the high-concentration impurity region 241. The pinning electrodes 242 are disposed in a lattice pattern to surround the pixels 20 and the high-concentration impurity regions 241. The pinning electrodes 242 of the respective pixels 20 disposed in the pixel boundary regions 24 in the first direction X and the second direction Y are connected to each other.

FIG. 16 is a cross-sectional view taken along line C-C in FIG. 15. FIG. 16 illustrates a cross-sectional structure of two of the pixels 20 adjacent in the first direction X. In FIG. 16, the light incident surface is illustrated on the lower side. The configuration of the pixel 20 in FIG. 16 is similar to that of the pixel 20 of the first embodiment of the present disclosure illustrated in FIG. 4A. In the pixel boundary region 24 in FIG. 16, the high-concentration impurity region 241, the pinning electrode 242 (third electrode), and the electrode 243 (fourth electrode) are provided.

The electrode 243 is provided to establish conduction with the contact layer 201, and a voltage level of the contact layer 201 can be set by applying a predetermined voltage to the electrode 243. The electrode 243 is provided on an opposite surface side with respect to the light incident surface side of the pixel 20 and is connected to the high-concentration impurity region 241. The high-concentration impurity region 241 is connected to the contact layer 201. Therefore, the electrode 243 is electrically connected to the contact layer 201 via the high-concentration impurity region 241. Details of the high-concentration impurity region 241 are similar to those of the high-concentration impurity region 211 in FIG. 4A, and the high-concentration impurity region 241 contains impurities at a high concentration to the extent of having conductivity.

The pinning electrode 242 is used to induce a specific charge (for example, a hole) in the high-concentration impurity region 241. The pinning electrode 242 is disposed to surround the high-concentration impurity region 241. Furthermore, between the pinning electrode 242, and each of the electrode 243 and the high-concentration impurity region 241, an insulating material is disposed.

As described above, in the imaging device 1 according to the second embodiment of the present disclosure illustrated in FIG. 16, conduction with the contact layer 201 is established by the electrode 243 and the high-concentration impurity region 241 disposed in the pixel boundary region 24. In addition, a specific charge is induced in the high-concentration impurity region 241 by the pinning electrode 242 disposed in the pixel boundary region 24.

### Steps of Manufacturing Imaging Device according to Second Embodiment of Present Disclosure

Next, an outline of steps of manufacturing the imaging device 1 according to the second embodiment of the present disclosure will be described. Steps from formation of the laminate 4 as a base, formation of the trench to be the pixel boundary region 24, and to diffusion of impurities are similar to the manufacturing steps (FIGS. 7A to 7C) of the first embodiment of the present disclosure.

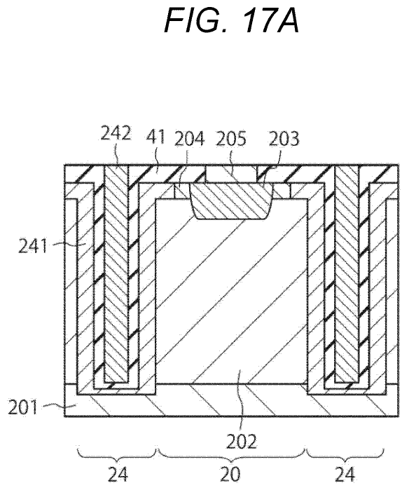

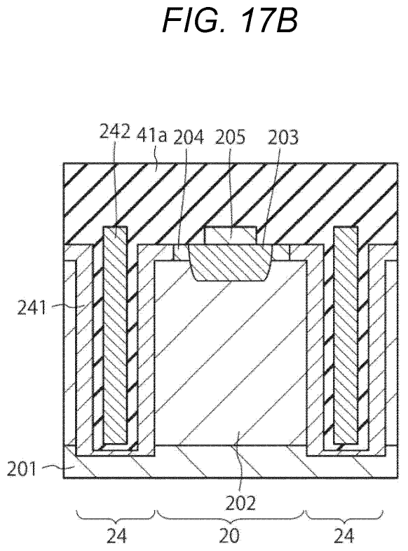

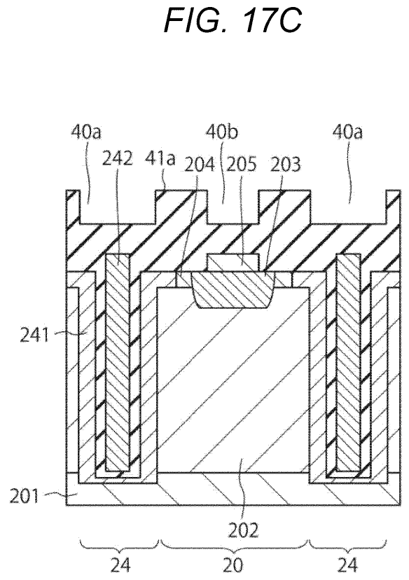

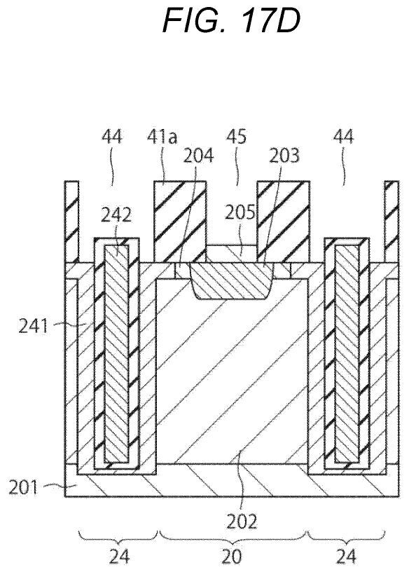

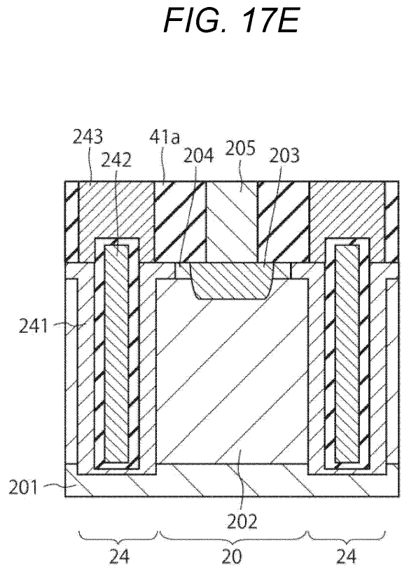

When the step of FIG. 7C is completed, next, as illustrated in FIG. 17A, the inner walls of the trenches 42 and 43 formed in FIG. 7C are covered with an insulating material, and the insulating material is further covered with a metal material. This metal material is for the pinning electrode 242 and the transfer electrode 205, and is a highly conductive material such as copper or aluminum, for example. Subsequently, as illustrated in FIG. 17B, an insulating layer 41a is formed on the opposite side of the contact layer 201. Thereafter, in the step of FIG. 17C, the insulating layer 41a formed in FIG. 17B is partially removed by etching or the like to form groove portions 40a and 40b. Next, as illustrated in FIG. 17D, the groove portion 40a is further dug to form a trench 44. As a result, the bottom of the trench 44 reaches the high-concentration impurity region 241. Similarly, the groove portion 40b is further dug to form a trench 45 also at the portion where the transfer electrode 205 is formed. On the other hand, the insulating layer 41a is left on the side of the pinning electrode 242 opposite to the light incident surface. Next, in the step of FIG. 17E, the inner parts of the trenches 44 and 45 in FIG. 17D are filled with a metal material. The metal material in the trench 44 forms the electrode 243, and the metal material in the trench 45 increases the thickness of the transfer electrode 205.

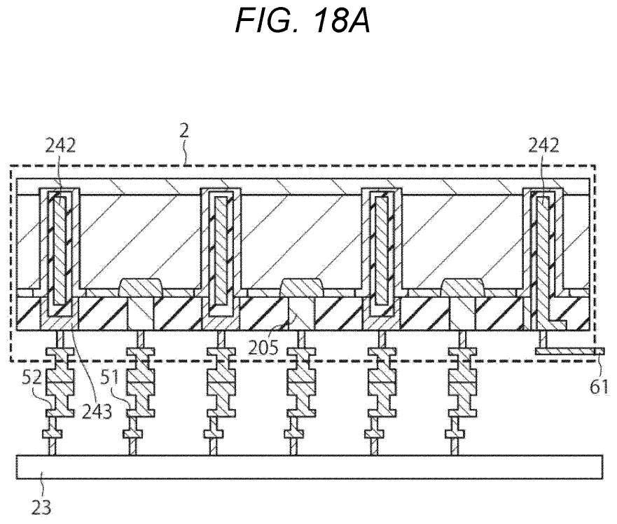

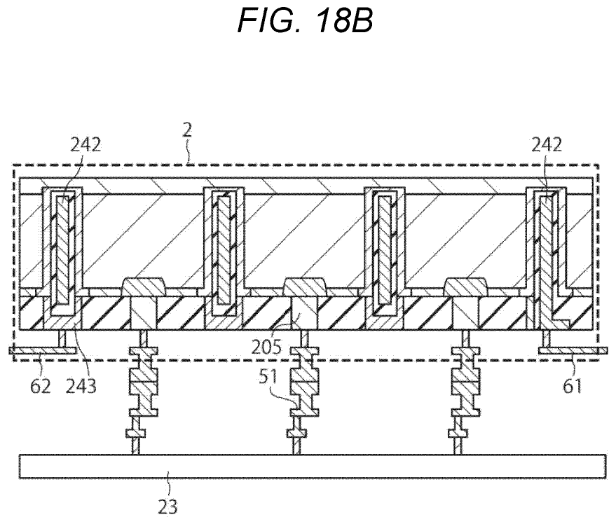

FIGS. 18A and 18B are cross-sectional views illustrating an example of wiring connection between the pixel 20 and the pixel circuit 23 according to the second embodiment of the present disclosure. In FIGS. 18A and 18B, the light incident rear surface side is illustrated on the upper side. In FIG. 18A, similarly to the wiring example of the first embodiment of the present disclosure illustrated in FIG. 8B, a first wiring region 51 and a second wiring region 52 are disposed for each pixel 20. The second wiring region 52 is connected to the electrode 243 of each pixel 20. In the wiring example illustrated in FIG. 18A, the pinning electrodes 242 of the respective pixels 20 are electrically connected to each other, for example, in the pixel boundary region 24 or in a wiring layer (not illustrated). In the example of FIG. 18A, the pinning electrode 242 in the pixel boundary region 24 on the peripheral edge side of the pixel region 2 is connected to the wiring region 61 extending to the outer peripheral side, and in a wiring region 61, the pinning electrodes 242 of the respective pixels 20 are set to the same voltage level.

FIG. 18B illustrates a cross-sectional structure in which the number of wiring regions is reduced as compared with FIG. 18A. In FIG. 18B, the wiring region is not connected to the electrode 243 in the pixel boundary region 24 other than the pixel boundary region 24 on the peripheral edge side of the pixel region 2. The wiring region 62 extending to the outer peripheral side is connected to the electrode 243 in the pixel boundary region 24 on the peripheral edge side, and in the wiring region 62, the electrodes 243 of the respective pixels 20 and the contact layer 201 are set to the same voltage level.

### First Modification of Second Embodiment of Present Disclosure

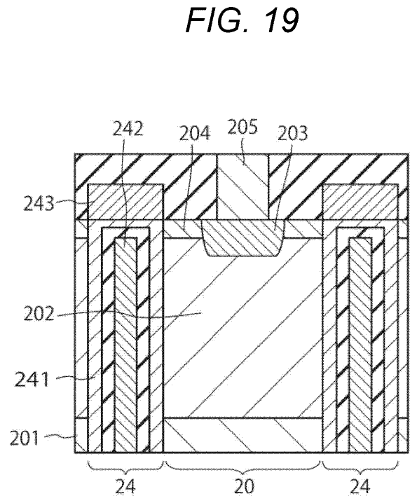

FIG. 19 is a cross-sectional view of an imaging device 1 in a first modification of the second embodiment of the present disclosure. A first modification of the second embodiment of the present disclosure is characterized in that the pixel boundary region 24 is formed from the light incident surface side. That is, in the imaging device 1 in FIG. 19, a trench is formed from the contact layer 201 side in the pixel boundary region 24. As a result, the pinning electrode 242 and the high-concentration impurity region 241 penetrate the contact layer 201.

### Second Modification of Second Embodiment of Present Disclosure

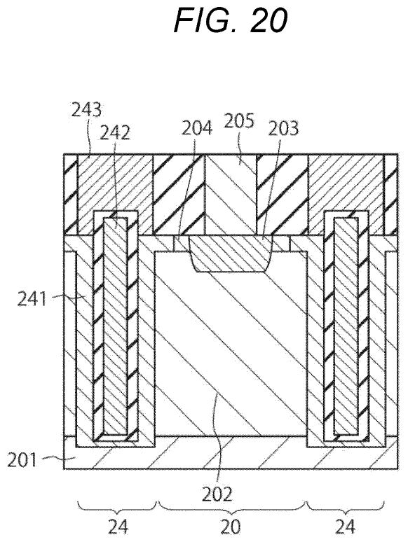

FIG. 20 is a cross-sectional view of an imaging device 1 in a second modification of the second embodiment of the present disclosure. The imaging device 1 illustrated in FIG. 20 has a polarity of each layer opposite to that of the imaging device 1 illustrated in FIG. 15. The imaging device 1 in FIG. 15 transfers electrons generated in the photoelectric conversion layer 202 to the transfer electrode 205, whereas the imaging device 1 in FIG. 20 transfers holes generated in the photoelectric conversion layer 202 to the transfer electrode 205. Furthermore, in FIGS. 15 and 20, the polarities of the charges induced in the high-concentration impurity region 241 are also opposite. More specifically, the high-concentration impurity region 241 in FIG. 20 contains a large amount of n-type impurities (for example, sulfur, germanium, or the like), and the impurity diffusion region 203 contains a large amount of p-type impurities (for example, zinc, magnesium, and the like).

As described above, in the second embodiment, the end portion, on the light incident surface side, of the high-concentration impurity region 241 disposed in the pixel boundary region 24 is connected to the contact layer 201, and the end portion, on the opposite surface side with respect to the light incident surface, of the high-concentration impurity region 241 is connected to the electrode 243. As a result, the voltage level of the contact layer 201 can be set by the voltage applied to the electrode 243, and it is not necessary to provide the transparent electrode 224 on the light incident surface side of the pixel 20. Furthermore, since the pinning electrode 242 is disposed in the pixel boundary region 24 to be separated from the high-concentration impurity region 241, a specific charge can be induced in the high-concentration impurity region 241 by controlling the voltage applied to the pinning electrode 242, and a dark current can be suppressed.

### Application Example

The technology according to the present disclosure can be applied to various products. For example, the technology according to the present disclosure may also be implemented as a device mounted on any kind of mobile body such as an automobile, an electric automobile, a hybrid electric automobile, a motorcycle, a bicycle, a personal mobility, an airplane, a drone, a ship, a robot, a construction machine, an agricultural machine (tractor), and the like.

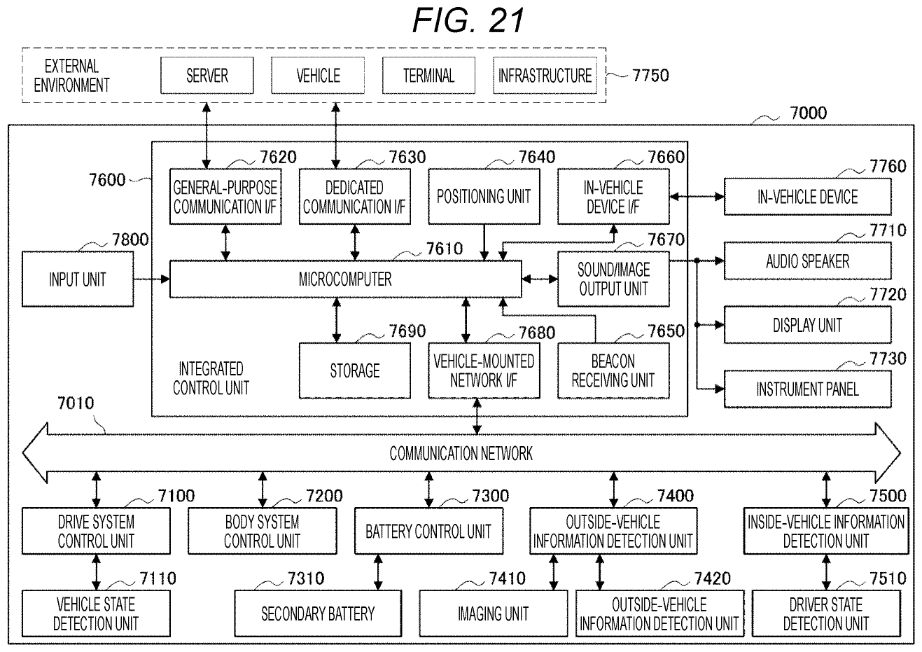

FIG. 21 is a block diagram illustrating a schematic configuration example of a vehicle control system 7000 as an example of a mobile body control system to which the technology according to the present disclosure can be applied. The vehicle control system 7000 includes a plurality of electronic control units connected to each other via a communication network 7010. In the example illustrated in FIG. 21, the vehicle control system 7000 includes a drive system control unit 7100, a body system control unit 7200, a battery control unit 7300, an outside-vehicle information detection unit 7400, an inside- vehicle information detection unit 7500, and an integrated control unit 7600. The communication network 7010 connecting the plurality of control units to each other may, for example, be a vehicle-mounted communication network compliant with an arbitrary standard such as controller area network (CAN), local interconnect network (LIN), local area network (LAN), FlexRay (registered trademark), or the like.

Each of the control units includes: a microcomputer that performs arithmetic processing according to various kinds of programs; a storage that stores the programs executed by the microcomputer, parameters used for various kinds of arithmetic processing, or the like; and a driving circuit that drives various kinds of control target devices. Each control unit includes a network I/F for communicating with other control units via the communication network 7010, and a communication I/F for communicating with devices, sensors, or the like inside and outside the vehicle by wired communication or wireless communication. In FIG. 21, as a functional configuration of the integrated control unit 7600, a microcomputer 7610, a general-purpose communication I/F 7620, a dedicated communication I/F 7630, a positioning unit 7640, a beacon receiving unit 7650, an in-vehicle device I/F 7660, a sound/image output unit 7670, a vehicle-mounted network I/F 7680, and a storage 7690 are illustrated. The other control units similarly include a microcomputer, a communication I/F, a storage, and the like.

The drive system control unit 7100 controls the operation of devices related to the drive system of the vehicle in accordance with various kinds of programs. For example, the drive system control unit 7100 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like. The drive system control unit 7100 may have a function as a control device for an antilock brake system (ABS), electronic stability control (ESC), or the like.

The drive system control unit 7100 is connected to a vehicle state detection unit 7110. The vehicle state detection unit 7110, for example, includes at least one of a gyro sensor that detects the angular velocity of axial rotational movement of a vehicle body, an acceleration sensor that detects an acceleration of the vehicle, and sensors that detects an amount of operation of the accelerator pedal, an amount of operation of the brake pedal, a steering angle of the steering wheel, an engine speed or a rotational speed of the wheels, and the like. The drive system control unit 7100 performs arithmetic processing using a signal input from the vehicle state detection unit 7110, and controls the internal combustion engine, a driving motor, an electric power steering device, a brake device, and the like.

The body system control unit 7200 controls the operation of various kinds of devices provided to the vehicle body in accordance with various kinds of programs. For example, the body system control unit 7200 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 7200. The body system control unit 7200 receives these input radio waves or signals, and controls a door lock device, a power window device, lamps, or the like of the vehicle.

The battery control unit 7300 controls a secondary battery 7310, which is a power supply source for the driving motor, in accordance with various kinds of programs. For example, the battery control unit 7300 is supplied with information about a battery temperature, a battery output voltage, an amount of charge remaining in the battery, or the like from a battery device including the secondary battery 7310. The battery control unit 7300 performs arithmetic processing using these signals, and performs control for regulating the temperature of the secondary battery 7310 or controls a cooling device provided to the battery device or the like.

The outside-vehicle information detection unit 7400 detects information about the outside of the vehicle including the vehicle control system 7000. For example, the outside-vehicle information detection unit 7400 is connected to at least one of an imaging unit 7410 and an outside-vehicle information detection unit 7420. The imaging unit 7410 includes at least one of a time-of-flight (ToF) camera, a stereo camera, a monocular camera, an infrared camera, and other cameras. The outside-vehicle information detection unit 7420 includes, for example, at least one of an environmental sensor for detecting current atmospheric conditions or weather conditions, a peripheral information detecting sensor for detecting another vehicle around the vehicle including the vehicle control system 7000, an obstacle, a pedestrian, or the like.

The environmental sensor may be, for example, at least one of a rain drop sensor detecting rain, a fog sensor detecting fog, a sunshine sensor detecting a degree of sunshine, or a snow sensor detecting snowfall. The peripheral information detecting sensor may be at least one of an ultrasonic sensor, a radar device, or a light detection and ranging device or laser imaging detection and ranging device (LIDAR device). Each of the imaging unit 7410 and the outside-vehicle information detection unit 7420 may be provided as an independent sensor or device, or may be provided as a device in which a plurality of sensors or devices is integrated.

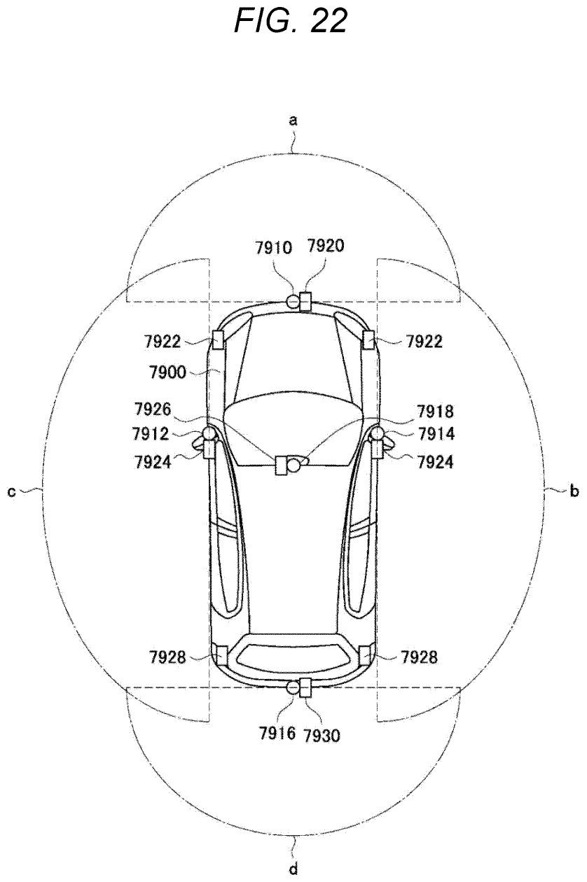

Here, FIG. 22 illustrates an example of installation positions of the imaging unit 7410 and the outside-vehicle information detection unit 7420. Each of imaging units 7910, 7912, 7914, 7916, and 7918 is provided, for example, at least one position of a front nose, a side mirror, a rear bumper, a rear door, and an upper portion of a windshield in a vehicle interior in a vehicle 7900. The imaging unit 7910 provided to the front nose and the imaging unit 7918 provided to the upper portion of the windshield in the vehicle interior mainly captures an image of the front of the vehicle 7900. The imaging units 7912 and 7914 provided to the sideview mirror mainly captures an image of the sides of the vehicle 7900. The imaging unit 7916 provided to the rear bumper or the back door mainly captures an image of the rear of the vehicle 7900. The imaging unit 7918 provided to the upper portion of the windshield in the vehicle interior is used mainly to detect a preceding vehicle, a pedestrian, an obstacle, a traffic light, a traffic sign, a lane, or the like.

Note that FIG. 22 illustrates an example of an imaging range of each of the imaging units 7910, 7912, 7914, and 7916. An imaging range a represents an imaging range of the imaging unit 7910 provided on the front nose, imaging ranges b and c respectively represent the imaging ranges of the imaging units 7912 and 7914 provided on the sideview mirrors, an imaging range d represents the imaging range of the imaging unit 7916 provided on the rear bumper or the rear door. A bird's-eye image of the vehicle 7900 as viewed from above can be obtained by superimposing image data imaged by the imaging units 7910, 7912, 7914, and 7916, for example.

Outside-vehicle information detection units 7920, 7922, 7924, 7926, 7928, and 7930 provided to the front, rear, sides, and corners of the vehicle 7900 and the upper portion of the windshield within the vehicle interior may be, for example, an ultrasonic sensor or a radar device. The outside-vehicle information detection units 7920, 7926, and 7930 provided to the front nose, the rear bumper, and the back door of and the upper portion of the windshield in the vehicle interior of the vehicle 7900 may be a LIDAR device, for example. These outside-vehicle information detection units 7920 to 7930 are used mainly to detect a preceding vehicle, a pedestrian, an obstacle, and the like.

Referring back to FIG. 21, the description will be continued. The outside-vehicle information detection unit 7400 causes the imaging unit 7410 to capture an image outside the vehicle, and receives the captured image data. In addition, the outside-vehicle information detection unit 7400 receives detection information from the outside-vehicle information detection unit 7420 connected to the outside-vehicle information detection unit 7400. In a case where the outside-vehicle information detection unit 7420 is an ultrasonic sensor, a radar device, or a LIDAR device, the outside-vehicle information detection unit 7400 transmits an ultrasonic wave, an electromagnetic wave, or the like, and receives information of a received reflected wave. On the basis of the received information, the outside-vehicle information detection unit 7400 may perform processing of detecting an object such as a human, a vehicle, an obstacle, a sign, a character on a road surface, or the like, or processing of detecting a distance thereto. The outside-vehicle information detection unit 7400 may perform environment recognition processing of recognizing rainfall, fog, road surface conditions, or the like on the basis of the received information. The outside-vehicle information detection unit 7400 may calculate a distance to an object outside the vehicle on the basis of the received information.

In addition, on the basis of the received image data, the outside-vehicle information detection unit 7400 may perform image recognition processing of recognizing a human, a vehicle, an obstacle, a sign, a character on a road surface, or the like, or processing of detecting a distance thereto. The outside-vehicle information detection unit 7400 may subject the received image data to processing such as distortion correction, alignment, or the like, and combine the image data of images captured by a plurality of different imaging units 7410 to generate a bird's-eye image or a panoramic image. The outside-vehicle information detection unit 7400 may perform a viewpoint conversion processing, using the image data of images captured by different imaging units 7410.

The inside-vehicle information detection unit 7500 detects information about the inside of the vehicle. The inside-vehicle information detection unit 7500 is, for example, connected to a driver state detection unit 7510 that detects the state of a driver. The driver state detection unit 7510 may include a camera that images the driver, a biosensor that detects biological information of the driver, a microphone that collects sound within the vehicle interior, or the like. The biosensor is, for example, disposed in a seat surface, the steering wheel, or the like, and detects biological information of an occupant sitting on a seat or the driver holding the steering wheel. On the basis of detection information input from the driver state detection unit 7510, the inside-vehicle information detection unit 7500 may calculate a degree of fatigue of the driver or a degree of concentration of the driver, or may determine whether the driver is dozing. The inside-vehicle information detection unit 7500 may subject an audio signal obtained by the collection of the sound to processing such as noise canceling processing or the like.

The integrated control unit 7600 controls the overall operation in the vehicle control system 7000 in accordance with various kinds of programs. The integrated control unit 7600 is connected to an input unit 7800. The input unit 7800 is implemented by a device that can be operated by an occupant, such as a touch panel, a button, a microphone, a switch, a lever, for example. The integrated control unit 7600 may be supplied with data obtained by voice recognition of voice input through the microphone. The input unit 7800 may, for example, be a remote control device using infrared rays or other radio waves, or an external connecting device such as a mobile phone, a personal digital assistant (PDA), or the like that supports operation of the vehicle control system 7000. The input unit 7800 may be, for example, a camera. In that case, an occupant can input information by gesture. Alternatively, data may be input which is obtained by detecting the movement of a wearable device that an occupant wears. Further, the input unit 7800 may, for example, include an input control circuit or the like that generates an input signal on the basis of information input by an occupant or the like, using the above-described input unit 7800, and outputs the generated input signal to the integrated control unit 7600. An occupant or the like inputs various kinds of data or gives an instruction for processing operation to the vehicle control system 7000 by operating the input unit 7800.

The storage 7690 may include a read only memory (ROM) that stores various kinds of programs executed by the microcomputer and a random access memory (RAM) that stores various kinds of parameters, operation results, sensor values, or the like. In addition, the storage 7690 may be implemented by a magnetic storage device such as a hard disc drive (HDD) or the like, a semiconductor storage device, an optical storage device, a magneto-optical storage device, or the like.

The general-purpose communication I/F7620 is a general-purpose communication I/F that mediates communication with various devices present in the external environment 7750. The general-purpose communication I/F 7620 may implement a cellular communication protocol such as global system of mobile communications (GSM) (registered trademark), worldwide interoperability for microwave access (WiMAX (registered trademark)), long term evolution (LTE (registered trademark)), or LTE-advanced (LTE-A), or another wireless communication protocol such as wireless LAN (referred to also as wireless fidelity (Wi-Fi) (registered trademark)) or Bluetooth (registered trademark). The general-purpose communication I/F 7620 may, for example, connect to a device (for example, an application server or a control server) present in the external network (for example, the Internet, a cloud network, or a company-specific network) via a base station or an access point. In addition, the general-purpose communication I/F 7620 may connect to a terminal present in the vicinity of the vehicle (for example, a terminal of the driver, a pedestrian, or a store, or a machine type communication (MTC) terminal) using a peer to peer (P2P) technology, for example.

The dedicated communication I/F 7630 is a communication I/F that supports a communication protocol developed for use in vehicles. The dedicated communication I/F 7630 may implement a standard protocol such, for example, as wireless access in vehicle environment (WAVE), which is a combination of institute of electrical and electronic engineers (IEEE) 802.11p as a lower layer and IEEE 1609 as a higher layer, dedicated short range communications (DSRC), or a cellular communication protocol. The dedicated communication I/F 7630 typically carries out V2X communication as a concept including one or more of communication between a vehicle and a vehicle (Vehicle to Vehicle), communication between a road and a vehicle (Vehicle to Infrastructure), communication between a vehicle and a home (Vehicle to Home), and communication between a pedestrian and a vehicle (Vehicle to Pedestrian).

The positioning unit 7640, for example, performs positioning by receiving a global navigation satellite system (GNSS) signal from a GNSS satellite (for example, a GPS signal from a global positioning system (GPS) satellite), and generates positional information including the latitude, longitude, and altitude of the vehicle. Incidentally, the positioning unit 7640 may identify a current position by exchanging signals with a wireless access point, or may obtain the positional information from a terminal such as a mobile phone, a personal handyphone system (PHS), or a smart phone that has a positioning function.

The beacon receiving unit 7650, for example, receives a radio wave or an electromagnetic wave transmitted from a radio station installed on a road or the like, and thereby obtains information about the current position, congestion, a closed road, a necessary time, or the like. Incidentally, the function of the beacon receiving unit 7650 may be contained in the dedicated communication I/F 7630 described above.

The in-vehicle device I/F 7660 is a communication interface that mediates connection between the microcomputer 7610 and various in-vehicle devices 7760 present within the vehicle. The in-vehicle device I/F 7660 may establish wireless connection using a wireless communication protocol such as wireless LAN, Bluetooth (registered trademark), near field communication (NFC), or wireless universal serial bus (WUSB). In addition, the in-vehicle device I/F 7660 may establish wired connection by universal serial bus (USB), high-definition multimedia interface (HDMI (registered trademark)), mobile high-definition link (MHL), or the like via a connection terminal (and a cable if necessary) not illustrated in the figures. The in-vehicle devices 7760 may, for example, include at least one of a mobile device or a wearable device possessed by an occupant, or an information device carried into or attached to the vehicle. Furthermore, the in-vehicle devices 7760 may also include a navigation device that searches for a path to an arbitrary destination. The in-vehicle device I/F 7660 exchanges control signals or data signals with these in-vehicle devices 7760.

The vehicle-mounted network I/F 7680 is an interface that mediates communication between the microcomputer 7610 and the communication network 7010. The vehicle-mounted network I/F 7680 transmits and receives signals or the like in conformity with a predetermined protocol supported by the communication network 7010.

The microcomputer 7610 of the integrated control unit 7600 controls the vehicle control system 7000 in accordance with various kinds of programs on the basis of information obtained via at least one of the general-purpose communication I/F 7620, the dedicated communication I/F 7630, the positioning unit 7640, the beacon receiving unit 7650, the in-vehicle device I/F 7660, and the vehicle-mounted network I/F 7680. For example, the microcomputer 7610 may calculate a control target value for the driving force generating device, the steering mechanism, or the braking device on the basis of the obtained information about the inside and outside of the vehicle, and output a control command to the drive system control unit 7100. For example, the microcomputer 7610 may perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like. In addition, the microcomputer 7610 may perform cooperative control intended for automated driving, which makes the vehicle to travel autonomously without depending on the operation of the driver, or the like, by controlling the driving force generating device, the steering mechanism, the braking device, or the like on the basis of the obtained information about the surroundings of the vehicle.

The microcomputer 7610 may generate three-dimensional distance information between the vehicle and an object such as a surrounding structure, a person, or the like, and generate local map information including information about the surroundings of the current position of the vehicle, on the basis of information obtained via at least one of the general-purpose communication I/F 7620, the dedicated communication I/F 7630, the positioning unit 7640, the beacon receiving unit 7650, the in-vehicle device I/F 7660, and the vehicle-mounted network I/F 7680. In addition, the microcomputer 7610 may predict danger such as collision of the vehicle, approaching of a pedestrian or the like, an entry to a closed road, or the like on the basis of the obtained information, and generate a warning signal. The warning signal may, for example, be a signal for producing a warning sound or lighting a warning lamp.

The sound/image output unit 7670 transmits an output signal of at least one of a sound and an image to an output device capable of visually or auditorily notifying information to an occupant of the vehicle or the outside of the vehicle. In the example of FIG. 21, an audio speaker 7710, a display unit 7720, and an instrument panel 7730 are illustrated as the output device. The display unit 7720 may include, for example, at least one of an on-board display or a head-up display. The display unit 7720 may have an augmented reality (AR) display function. The output device may be other than these devices, and may be another device such as headphones, a wearable device such as an eyeglass type display worn by an occupant or the like, a projector, a lamp, or the like. In a case where the output device is a display device, the display device visually displays results obtained by various kinds of processing performed by the microcomputer 7610 or information received from another control unit in various forms such as text, an image, a table, a graph, or the like. In addition, in a case where the output device is an audio output device, the audio output device converts an audio signal constituted of reproduced audio data or sound data or the like into an analog signal, and auditorily outputs the analog signal.

Note that, in the example illustrated in FIG. 21, at least two control units connected to each other via the communication network 7010 may be integrated into one control unit. Alternatively, each individual control unit may include a plurality of control units. Further, the vehicle control system 7000 may include another control unit not illustrated in the figures. In addition, part or the whole of the functions performed by one of the control units in the above description may be assigned to another control unit. That is, predetermined arithmetic processing may be performed by any of the control units as long as information is transmitted and received via the communication network 7010. Similarly, a sensor or a device connected to one of the control units may be connected to another control unit, and a plurality of control units may mutually transmit and receive detection information via the communication network 7010.

Note that the present technology may have the following configurations.

(1) An imaging device including:
a plurality of pixels; and
a pixel boundary region disposed between two of the pixels adjacent to each other, in which
each of the pixels includes:
a photoelectric conversion layer containing a compound semiconductor material;
a first electrode that is disposed on a light incident surface side of the photoelectric conversion layer and contains a compound semiconductor material; and
a second electrode that is disposed on an opposite surface side with respect to the light incident surface side of the photoelectric conversion layer and transfers a charge photoelectrically converted in the photoelectric conversion layer, and
the pixel boundary region includes:
a high-concentration impurity region extending from the light incident surface side to the opposite surface side;
a third electrode electrically insulated from the high-concentration impurity region and disposed along the high-concentration impurity region; and
a fourth electrode electrically conducted to the first electrode.

(2) The imaging device according to (1), in which the high-concentration impurity region has an impurity content per unit volume higher than the photoelectric conversion layer.

(3) The imaging device according to (1) or (2), in which the third electrode is set to a voltage that induces a specific charge in the high-concentration impurity region.

(4) The imaging device according to (3), in which the specific charge is a charge having a polarity different from a polarity of a charge photoelectrically converted in the photoelectric conversion layer and transferred to the second electrode.

(5) The imaging device according to any one of (1) to (4), in which
the first electrode is a semiconductor layer containing a compound semiconductor material different from the compound semiconductor material of the photoelectric conversion layer.

(6) The imaging device according to any one of (1) to (5),
in which the fourth electrode is disposed from the opposite surface side with respect to the light incident surface side of the photoelectric conversion layer to a height reacting the first electrode.

(7) The imaging device according to (6), in which the third electrode is disposed between the fourth electrode and the high-concentration impurity region.

(8) The imaging device according to (6) or (7), in which the third electrode is disposed from the opposite surface side with respect to the light incident surface side of the photoelectric conversion layer to a height not reaching the first electrode.

(9) The imaging device according to any one of (6) to (8), in which the high-concentration impurity region is disposed to surround the pixel, and
the third electrode is disposed to surround the high-concentration impurity region for each of the pixels.

(10) The imaging device according to any one of (6) to (9), in which
the plurality of pixels is arranged in a first direction and a second direction,
two of the third electrodes included in two of the pixels disposed adjacent to each other in the first direction are connected at the pixel boundary region between the two of the pixels disposed adjacent to each other in the first direction, and
two of the third electrodes included in two of the pixels disposed adjacent to each other in the second direction are connected at the pixel boundary region between the two of the pixels disposed adjacent to each other in the second direction.

(11) The imaging device according to any one of (6) to (10), in which
the fourth electrode is disposed in the pixel boundary region between two of the pixels disposed adjacent to each other in a diagonal direction.

(12) The imaging device according to any one of (6) to (11) further including
a wiring layer disposed on the opposite surface side with respect to the light incident surface side of the photoelectric conversion layer, in which
the wiring layer includes, for each of the pixels:
a first wiring region electrically conducted to the second electrode; and
a second wiring region electrically conducted to the fourth electrode.

(13) The imaging device according to (12), in which the wiring layer includes, for each of the pixels, a third wiring region electrically conducted to the third electrode.

(14) The imaging device according to any one of (1) to (5), in which
an end portion of the high-concentration impurity region on the light incident surface side is connected to the first electrode, and
an end portion of the high-concentration impurity region on the opposite surface side with respect to the light incident surface side is connected to the fourth electrode.

(15) The imaging device according to (14), in which
the high-concentration impurity region is disposed to surround the pixel, and
the fourth electrode is disposed to surround the high-concentration impurity region for each of the pixels.

(16) The imaging device according to (14) or (15), in which
the third electrode is disposed in a lattice pattern in a plurality of the pixel boundary regions between the plurality of pixels.

(17) The imaging device according to any one of (14) to (16) further including a wiring layer disposed on the opposite surface side with respect to the light incident surface side of the photoelectric conversion layer, in which
the wiring layer includes, for each of the pixels, a first wiring region electrically conducted to the second electrode.

(18) The imaging device according to (17), in which the wiring layer includes, for each of the pixels, a second wiring region electrically conducted to the fourth electrode.

(19) The imaging device according to any one of (1) to (18), in which
a plurality of the third electrodes provided in a plurality of the pixel boundary regions between the plurality of pixels is electrically conducted to each other, and
a plurality of the fourth electrodes provided in a plurality of the pixel boundary regions is electrically conducted to each other.

Aspects of the present disclosure are not limited to the above-described individual embodiments, but include various modifications that can be conceived by those skilled in the art, and the effects of the present disclosure are not limited to the above-described contents. That is, various additions, modifications, and partial deletions are possible without departing from the conceptual idea and spirit of the present disclosure derived from the matters defined in the claims and equivalents thereof.

### REFERENCE SIGNS LIST

1, 100, 100a Imaging device
2 Pixel region
3 Circuit unit
4 Laminate
11 Pixel chip
12 Circuit chip
20 Pixel
21, 24 Pixel boundary region
23 Pixel circuit
31 Row scanning unit
32 Horizontal selection unit
33 Column scanning unit
34 System control unit
35 Pixel drive line
36, 37 Signal line
40a, 40b Groove portion
41, 41a Insulating layer
42, 43, 44, 45 Trench
42a Groove region
51 First wiring region
52 Second wiring region
53 Third wiring region
61, 62 Wiring region
201, 204 Contact layer
202 Photoelectric conversion layer
203 Impurity diffusion region
205 Transfer electrode
211, 241 High-concentration impurity region
212, 242 Pinning electrode
213 Through electrode
221 First semiconductor layer
222 Second semiconductor layer
223 Diffusion layer
224 Transparent electrode
243 Electrode

1. An imaging device comprising:
a plurality of pixels; and
a pixel boundary region disposed between two of the pixels adjacent to each other, wherein
each of the pixels includes:
a photoelectric conversion layer containing a compound semiconductor material;
a first electrode that is disposed on a light incident surface side of the photoelectric conversion layer and contains a compound semiconductor material; and
a second electrode that is disposed on an opposite surface side with respect to the light incident surface side of the photoelectric conversion layer and transfers a charge photoelectrically converted in the photoelectric conversion layer, and
the pixel boundary region includes:
a high-concentration impurity region extending from the light incident surface side to the opposite surface side;
a third electrode electrically insulated from the high-concentration impurity region and disposed along the high-concentration impurity region; and
a fourth electrode electrically conducted to the first electrode.

2. The imaging device according to claim 1, wherein the high-concentration impurity region has an impurity content per unit volume higher than the photoelectric conversion layer.

3. The imaging device according to claim 1, wherein the third electrode is set to a voltage that induces a specific charge in the high-concentration impurity region.

4. The imaging device according to claim 3, wherein the specific charge is a charge having a polarity different from a polarity of a charge photoelectrically converted in the photoelectric conversion layer and transferred to the second electrode.

5. The imaging device according to claim 1, wherein
the first electrode is a semiconductor layer containing a compound semiconductor material different from the compound semiconductor material of the photoelectric conversion layer.

6. The imaging device according to claim 1,
wherein the fourth electrode is disposed from the opposite surface side with respect to the light incident surface side of the photoelectric conversion layer to a height reacting the first electrode.

7. The imaging device according to claim 6, wherein the third electrode is disposed between the fourth electrode and the high-concentration impurity region.

8. The imaging device according to claim 6, wherein the third electrode is disposed from the opposite surface side with respect to the light incident surface side of the photoelectric conversion layer to a height not reaching the first electrode.

9. The imaging device according to claim 6, wherein the high-concentration impurity region is disposed to surround the pixel, and
the third electrode is disposed to surround the high-concentration impurity region for each of the pixels.

10. The imaging device according to claim 6, wherein
the plurality of pixels is arranged in a first direction and a second direction,
two of the third electrodes included in two of the pixels disposed adjacent to each other in the first direction are connected at the pixel boundary region between the two of the pixels disposed adjacent to each other in the first direction, and
two of the third electrodes included in two of the pixels disposed adjacent to each other in the second direction are connected at the pixel boundary region between the two of the pixels disposed adjacent to each other in the second direction.

11. The imaging device according to claim 6, wherein
the fourth electrode is disposed in the pixel boundary region between two of the pixels disposed adjacent to each other in a diagonal direction.

12. The imaging device according to claim 6 further comprising a wiring layer disposed on the opposite surface side with respect to the light incident surface side of the photoelectric conversion layer, wherein
the wiring layer includes, for each of the pixels:
a first wiring region electrically conducted to the second electrode; and
a second wiring region electrically conducted to the fourth electrode.

13. The imaging device according to claim 12, wherein the wiring layer includes, for each of the pixels, a third wiring region electrically conducted to the third electrode.

14. The imaging device according to claim 1, wherein
an end portion of the high-concentration impurity region on the light incident surface side is connected to the first electrode, and
an end portion of the high-concentration impurity region on the opposite surface side with respect to the light incident surface side is connected to the fourth electrode.

15. The imaging device according to claim 14, wherein
the high-concentration impurity region is disposed to surround the pixel, and
the fourth electrode is disposed to surround the high-concentration impurity region for each of the pixels.

16. The imaging device according to claim 14, wherein
the third electrode is disposed in a lattice pattern in a plurality of the pixel boundary regions between the plurality of pixels.

17. The imaging device according to claim 14 further comprising a wiring layer disposed on the opposite surface side with respect to the light incident surface side of the photoelectric conversion layer, wherein
the wiring layer includes, for each of the pixels, a first wiring region electrically conducted to the second electrode.

18. The imaging device according to claim 17, wherein
the wiring layer includes, for each of the pixels, a second wiring region electrically conducted to the fourth electrode.

19. The imaging device according to claim 1, wherein
a plurality of the third electrodes provided in a plurality of the pixel boundary regions between the plurality of pixels is electrically conducted to each other, and
a plurality of the fourth electrodes provided in a plurality of the pixel boundary regions is electrically conducted to each other.
